(19) United States
(12) Patent Application Publication
(10) Pub. No.: US 2016/0343913 A1
(43) Pub. Date: Nov. 24, 2016

(54) LIGHT-EMITTING DEVICE

(71) Applicant: Epistar Corporation, Hsinchu (TW)

(72) Inventors: Wei-Fan KE, Hsinchu (TW); Tzu-Chieh HSU, Hsinchu (TW); Yu-Ren PENG, Hsinchu (TW)

(21) Appl. No.: 14/719,694

(22) Filed: May 22, 2015

(51) Int. Cl. H01L 33/42; H01L 33/22; H01L 33/30; H01L 33/06

(52) U.S. Cl. CPC H01L 33/42; H01L 33/06; H01L 33/22; H01L 33/30; H01L 2933/0016

(57) ABSTRACT

The present disclosure provides a light-emitting device. The light-emitting device comprises a light-emitting stack comprising an active layer and a first surface comprising a roughened area; a smoothing layer on the first surface, wherein the smoothing layer has a surface smoother than the first surface; and a transparent conductive layer on the smoothing layer. A method for forming the light-emitting device is also disclosed.

### FIELD OF DISCLOSURE

The present disclosure relates to a light-emitting device, in particular to a light-emitting device comprising a smoothing layer.

### BACKGROUND OF THE DISCLOSURE

A light-emitting diode (LED) is suitable for diverse applications because it has several advantages of low power consumption, low heat generation, long life, shock tolerance, compact, swift response, and stable output wavelength.

FIG. 1 shows a cross-sectional view of a conventional light-emitting diode 10. As shown in FIG. 1, the light-emitting diode 10 comprises a permanent substrate 11. A light-emitting stack 12, a metal reflective layer 13, a barrier layer 14, and a bonding structure 15 are disposed on the permanent substrate 11 from top to bottom. In addition, a first bonding pad 110E1 and an extending electrode 110E1′ thereof is disposed on the light-emitting stack 12, and a second bonding pad 110E2 is disposed on the permanent substrate 11. Driving current from an external power device is injected through the first bonding pad 110E1 and the second bonding pad 110E2 and is spreaded over the light-emitting stack 12 through the extending electrode 110E1′. The extending electrode 110E1′ is usually made of metal material to achieve good conductivity. However, the extending electrode 110E1′ made of metal material shields or absorbs light emitted from the light-emitting stack 12 and results in a loss of light intensity.

### SUMMARY OF THE DISCLOSURE

The present disclosure provides a light-emitting device. The light-emitting device comprises a light-emitting stack comprising an active layer and a first surface comprising a roughened area; a smoothing layer on the first surface, wherein the smoothing layer has a surface smoother than the first surface; and a transparent conductive layer on the smoothing layer.

A method for forming the light-emitting device is also disclosed. The method for forming the light-emitting device comprises forming a light-emitting stack comprising an active layer and a first surface comprising a roughened area; forming a smoothing layer on the first surface, wherein the smoothing layer has a surface smoother than the first surface; and forming a transparent conductive layer on the smoothing layer.

### BRIEF DESCRIPTION OF THE DRAWINGS

FIG. 1 shows a conventional light-emitting diode.

FIGS. 2A to 2I show a method for forming a light-emitting device in accordance with an embodiment of the present application.

FIG. 3 shows a top view of the light-emitting device in FIG. 2I.

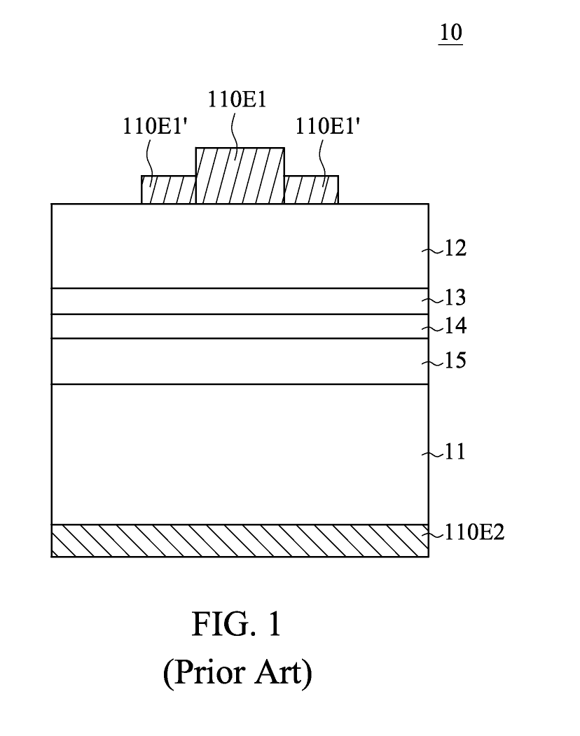

### DETAILED DESCRIPTION OF THE DISCLOSURE

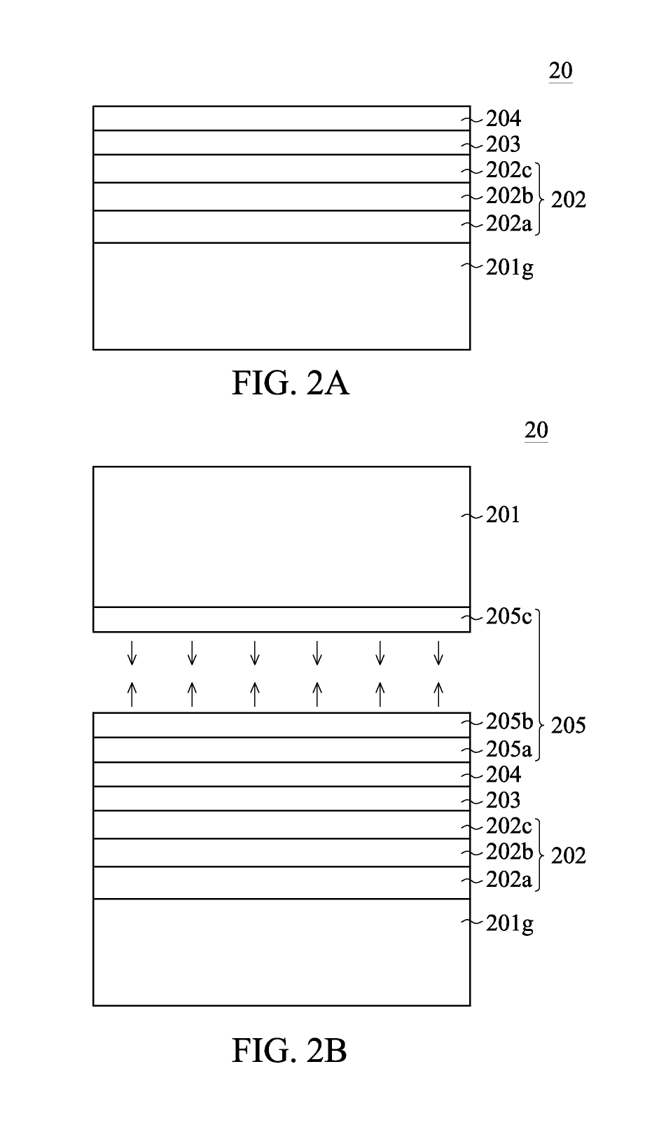

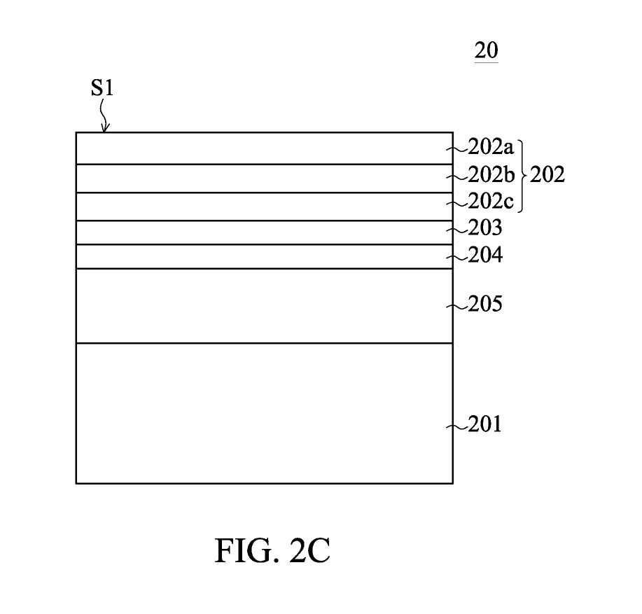

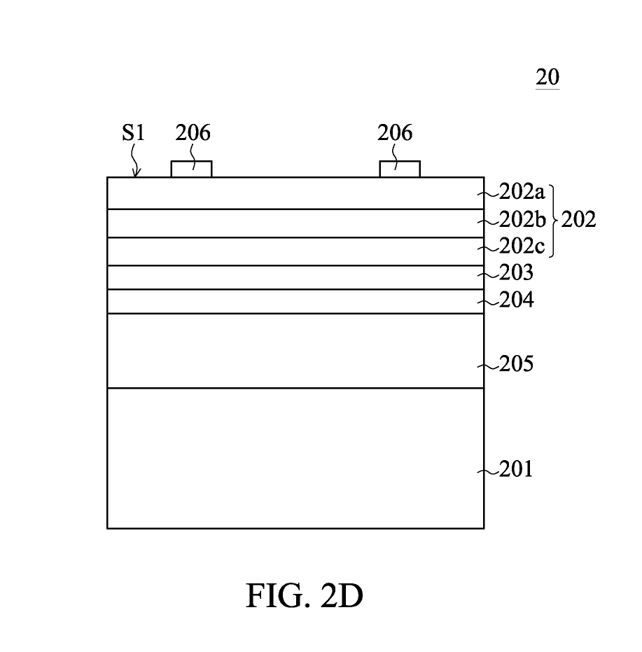

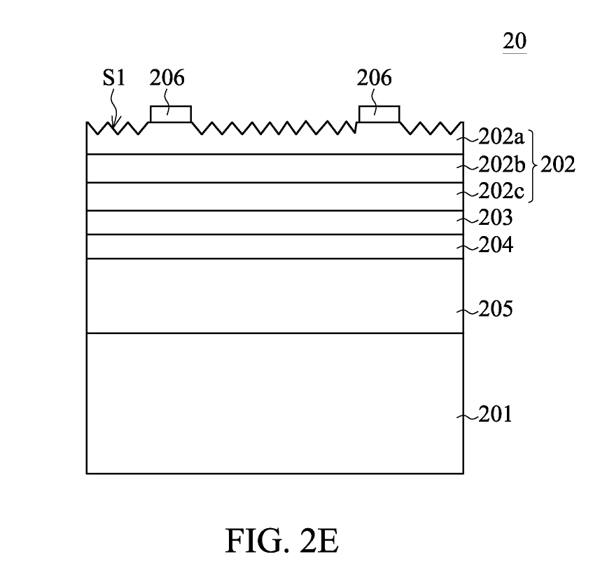

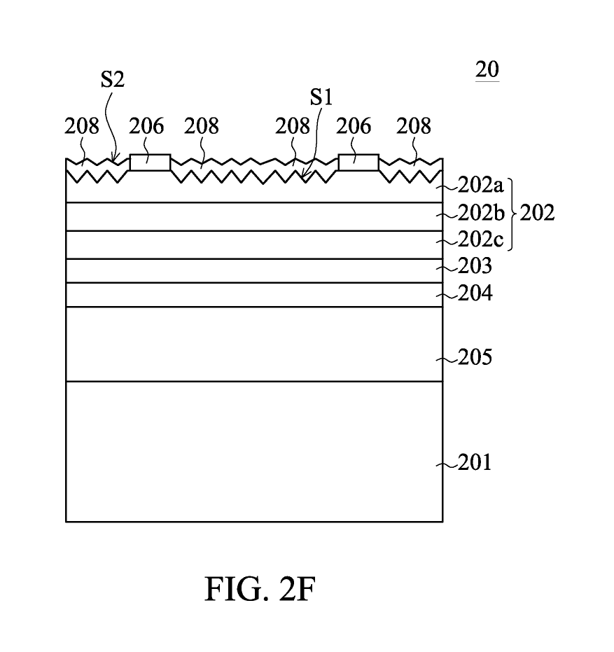

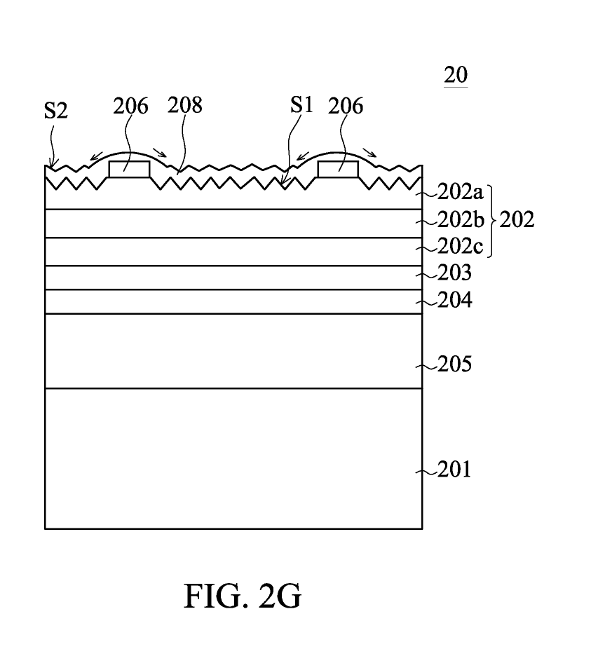

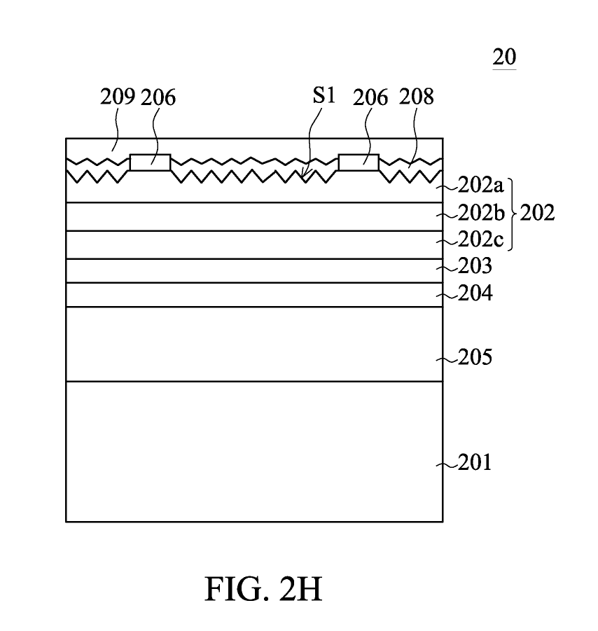

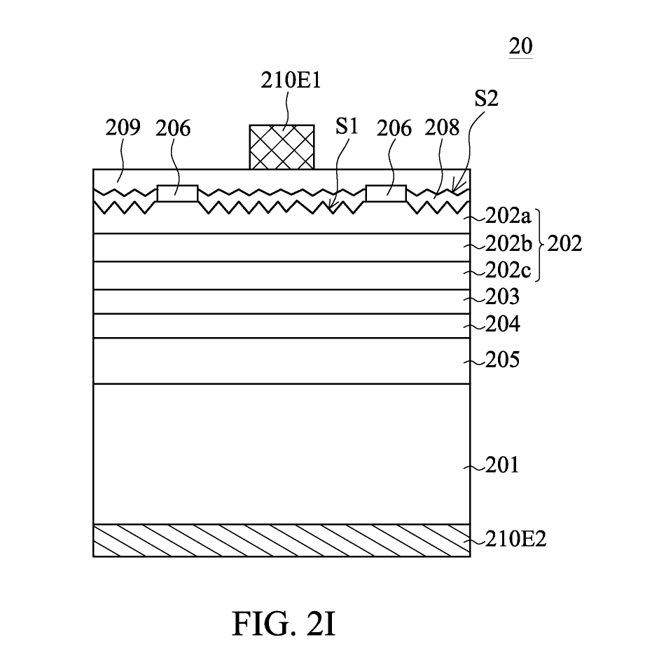

FIGS. 2A to 2I show a method for forming a light-emitting device in accordance with an embodiment of the present application. As shown in FIG. 2A, the method for forming a light-emitting device comprises providing a growth substrate 201g, forming a light-emitting stack 202 on the growth substrate 201g, forming a transparent conductive layer 203 on the light-emitting stack 202, and forming a reflective layer 204 on the transparent conductive layer 203. For example, the growth substrate 201g comprises a GaAs, GaP, AlN, SiC, or sapphire substrate. The light-emitting stack 202 comprises a first conductive type semiconductor layer 202a on the growth substrate 201g, an active layer 202b on the first conductive type semiconductor layer 202a, and a second conductive type semiconductor layer 202c on the active layer 202b. The first conductive type semiconductor layer 202a, the active layer 202b, and the second conductive type semiconductor layer 202c all comprise group III-V material. The first conductive type semiconductor layer 202a and the second conductive type semiconductor layer 202c are of different conductive types. For example, the first conductive type semiconductor layer 202a is an n-type semiconductor layer, and the second conductive type semiconductor layer 202c is a p-type semiconductor layer. The active layer 202b comprises a multiple quantum well (MQW) structure. When an external power is supplied, the carriers in the first conductive type semiconductor layer 202a and the second conductive type semiconductor layer 202c recombine in the active layer 202b to emit light. The transparent conductive layer 203 comprises a first transparent conductive oxide material, such as indium tin oxide (ITO), and forms an ohmic contact with the light-emitting stack 202. In an alternative embodiment, the transparent conductive layer 203 may be a multi-layer structure and further comprises a second transparent conductive oxide layer (not shown) formed on the first transparent conductive oxide layer, wherein the second transparent conductive oxide layer is for spreading current laterally and comprises a material different from that of the first transparent conductive oxide layer. In the present embodiment, the first transparent conductive oxide layer comprises indium tin oxide (ITO), and the second transparent conductive oxide layer comprises indium zinc oxide (IZO). In another embodiment, a material for the first transparent conductive oxide layer and the second transparent conductive oxide layer is selected from the group consisting of indium tin oxide (ITO), aluminum zinc oxide (AZO), cadmium tin oxide, antimony tin oxide, zinc oxide (ZnO), zinc tin oxide (ZTO), and indium zinc oxide (IZO). The reflective layer 204 comprises a metal material for reflecting light emitted by the light-emitting stack 202. In the present embodiment, the reflective layer 204 has a reflectivity greater than 80% to light emitted by the light-emitting stack 202. For example, the reflective layer 204 comprises gold (Au), silver (Ag), or Al (Aluminum). A barrier layer (not shown) is optionally disposed on the reflective layer 204 for preventing the metal material of the reflective layer 204 from diffusing into a metal connecting structure 205 as shown in FIG. 2B.

As shown in FIG. 2B, the method for forming a light-emitting device further comprises providing a permanent substrate 201. The permanent substrate 201 comprises a Si, Ge, SiC, AN, GaN, GaAs, GaP, CuW, or Cu substrate. A first bonding layer 205a and a second bonding layer 205b are formed on the reflective layer 204, and a third bonding layer 205c is formed on the permanent substrate 201. Then, the third bonding layer 205c is bonded to and the first bonding layer 205a and the second bonding layer 205b to form the metal connecting structure 205. In one embodiment, the first bonding layer 205a comprises gold (Au), the second bonding layer 205b comprises indium (In), and the third bonding layer 205c comprises gold (Au). The first bonding layer 205a, the second bonding layer 205b, and the third bonding layer 205c form an alloy of indium (In) and gold (Au) during a eutectic bonding process. In another embodiment, the first bonding layer 205a is formed on the reflective layer 204, and the second bonding layer 205b and the third bonding layer 205c are formed on the permanent substrate 201. Then, the second bonding layer 205b is bonded to the first bonding layer 205a. The first bonding layer 205a, the second bonding layer 205b, and the third bonding layer 205c form the metal connecting structure 205. As shown in FIG. 2C, the method for forming a light-emitting device further comprises removing the growth substrate 201g after the bonding step to expose a surface S1 of the first conductive type semiconductor layer 202a.

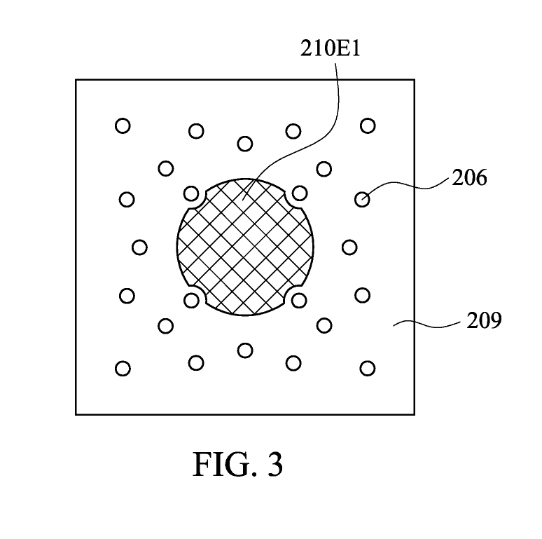

As shown in FIG. 2D, the method for forming a light-emitting device further comprises forming a patterned contact layer 206 on the surface S1. The patterned contact layer 206 comprises a material which forms an ohmic contact with the light-emitting stack 202. In the present embodiment, the patterned contact layer 206 comprises a layer of Au-Ge-Ni alloy with a thickness of about from 300 nm to 700 nm on the surface S1. The patterned contact layer 206 comprises a plurality of contact dots separated from each other when viewed from a top of the light-emitting device 20 as shown in FIG. 3. As shown in FIG. 2E, the method for forming a light-emitting device further comprises roughening an area of the surface S1 not covered by the patterned contact layer 206. The roughened area enhances the light being extracted out of the light-emitting device 20. A wet etching method is used for the roughening process. For example, a solution comprising a mixture of HNO₃, HAC (CH₃COOH), and BOE (Buffered Oxide Etch, which comprises a mixture of ammonium fluoride (NH₄F) and hydrofluoric acid (HF) is used for the wet etching method. A surface roughness Ra of the roughened area is greater than 0.5 μm, and typically between 0.5 μm and 2 μm, by measuring from a cross-sectional length of 50 μm of the surface S1. As shown in FIG. 2F, the method for forming a light-emitting device further comprises forming a smoothing layer 208 on the surface S1, wherein the smoothing layer 208 has a surface S2 smoother than the surface S1. A surface roughness Ra of the surface S2 of the smoothing layer is typically smaller than 100 nm, and is smaller than 50 nm in the present embodiment, by measuring from a cross-sectional length of 50 μm of the surface S2 of the smoothing layer. The smoothing layer 208 comprises a thermosetting material. The smoothing layer 208 can be formed by, for example, a spin-coating process, and then the coated material is treated by a thermally curing step. The smoothing layer 208 comprises an electrically conductive material or an electrically non-conductive material. For example, the electrically conductive material comprises a conducting polymer or a mixture of a non-conductive polymer and a conductive material. The non-conductive polymer comprises epoxy. The electrically non-conductive material comprises a non-conductive polymer or a mixture of a non-conductive polymer and other non-conductive material. For example, the non-conductive polymer comprises epoxy. The conducting polymer comprises poly (3,4-ethylenedioxythiophene) polystyrene sulfonate (i.e., PEDOT: PSS), and has an electrical resistivity smaller than 10⁻¹ Ω-m. The mixture of a non-conductive polymer and a conductive material comprises epoxy mixed with silver (Ag) nano-particles, carbon nanotubes (CNTs), or graphene flake having a thickness of about 30 nm and a dimension of about from 50 nm to 2 um. When the smoothing layer 208 comprises the mixture of epoxy and silver (Ag) nano-particles, the smoothing layer 208 forms an ohmic contact with the light-emitting stack 202 by the silver (Ag) nano-particles. Accordingly, an electrical path is formed through the smoothing layer 208 in addition to the patterned contact layer 206. A refractive index of the smoothing layer 208 is smaller than a refractive index of the light-emitting stack 202. The smoothing layer 208 comprises a transmittance over 70% to light emitted by the active layer. In one embodiment, poly (3,4-ethylenedioxythiophene) polystyrene sulfonate (i.e., PEDOT: PSS) with a viscosity of about 10˜130 cp is coated with a spin speed of about 500˜1500 rpm to form the smoothing layer 208. The smoothing layer 208 formed by the above method shows a good transmittance of 86.9% to light having a wavelength of 620 nm while has a sheet resistance of about 200 ohm per square, which is equal or close to a sheet resistance of a ITO film having a thickness of about 800 Å. In other words, the smoothing layer 208 can provide a layer with a smaller roughness than the roughness of the surface S1 and also improve current conducting between the contact dots of the patterned contact layer 206.

A quantity of the thermosetting material for forming the smoothing layer 208 can be controlled during the spin-coating process so that a thickness of the smoothing layer 208 is small enough that the smoothing layer 208 does not cover the patterned contact layer 206. In one embodiment, the smoothing layer 208 is formed through multiple times of spin-coating steps, wherein a relatively small quantity of the thermosetting material is provided in each coating. In an alternative embodiment, as shown in FIG. 2G, an ultrasonic treatment is applied to the smoothing layer 208 after the spin-coating process and prior to the thermal curing step. As indicated by the arrows in the figure, the ultrasonic treatment makes a part of the thermosetting material which is disposed on the patterned contact layer 206 flow toward a lower area, i.e., the area of the surface S1 not covered by the patterned contact layer 206.

As shown in FIG. 2H, the method for forming a light-emitting device further comprises forming a transparent conductive layer 209 on the smoothing layer 208. A refractive index of the transparent conductive layer 209 is smaller than or equal to a refractive index of the smoothing layer 208. The transparent conductive layer 209 comprises a transparent conductive oxide layer or a thin metal layer having a thickness less than 500 Å. A material for the transparent conductive oxide layer comprises indium tin oxide (ITO), aluminum zinc oxide (AZO), cadmium tin oxide, antimony tin oxide, zinc oxide (ZnO), zinc tin oxide (ZTO), or indium zinc oxide (IZO). The transparent conductive oxide layer may be formed by a sputtering method which provides better ability of gap filling. A material for the thin metal layer may be aluminum, gold, platinum, zinc, silver, nickel, germanium, indium, or tin, or the metal alloy thereof. As shown in FIG. 2I, the method for forming a light-emitting device further comprises forming an first bonding pad 210E1 on the transparent conductive layer 209, and forming an second bonding pad 210E2 on the permanent substrate 201 to formed a light-emitting device 20 as shown in FIG. 2I. The contact dot 206 is formed beyond an area covered by the first bonding pad 210E1 from a top view shown in FIG. 3.

As shown in FIG. 2I, the light-emitting device 20 is provided in accordance with the embodiment of the present application. The light-emitting device 20 comprises the permanent substrate 201. The light-emitting stack 202, the transparent conductive layer 203, the reflective layer 204, and the metal connecting structure 205 are on the permanent substrate 201 sequentially from the top to the bottom. The permanent substrate 201 comprises a Si, Ge, SiC, AlN, GaN, GaAs, GaP, CuW, or Cu substrate. The light-emitting stack 202 comprises the first surface S1 comprising an un-rough area on which the patterned contact layer 206 is disposed. The first surface S1 comprises the roughened area not covered by the patterned contact layer 206, and the light-emitting device 20 further comprises the smoothing layer 208 on the first surface S1, wherein the smoothing layer 208 has the surface S2 smoother than the first surface S1. A surface roughness Ra of the roughened area of the first surface S1 of the light-emitting stack 202 is greater than 0.5 μm, and typically between 0.5 μm and 2 μm, by measuring from a cross-sectional length of 50 μm of the first surface S1, and a surface roughness Ra of the surface S2 of the smoothing layer 208 is smaller than 100 nm, and is smaller than 50 nm in the present embodiment, by measuring from a cross-sectional length of 50 μm of the surface S2 of the smoothing layer 208. The light-emitting device 20 further comprises the transparent conductive layer 209 on the smoothing layer 208, the first bonding pad 210E1 on the transparent conductive layer 209, and the second bonding pad 210E2 is on the permanent substrate 201.

The light-emitting stack 202 comprises the first conductive type semiconductor layer 202a, the active layer 202b on the first conductive type semiconductor layer 202a, and the second conductive type semiconductor layer 202c on the active layer 202b. The first conductive type semiconductor layer 202a, the active layer 202b, and the second conductive type semiconductor layer 202c comprise group III-V material. The first conductive type semiconductor layer 202a and the second conductive type semiconductor layer 202c are of different conductive types. For example, the first conductive type semiconductor layer 202a is an n-type semiconductor layer, and the second conductive type semiconductor layer 202c is a p-type semiconductor layer. The active layer 202b comprises a multiple quantum well (MQW) structure. When an external power is supplied, the carriers in the first conductive type semiconductor layer 202a and the second conductive type semiconductor layer 202c recombine in the active layer 202b to emit light. The transparent conductive layer 203 comprises a first transparent conductive oxide material, such as indium tin oxide (ITO), and forms an ohmic contact with the light-emitting stack 202. In an alternative embodiment, the transparent conductive layer 203 may be a multi-layer structure and further comprises the second transparent conductive oxide layer (not shown) between the first transparent conductive oxide layer and the reflective layer 204, wherein the second transparent conductive oxide layer is for spreading current laterally and comprises a material different from that of the first transparent conductive oxide layer. In the present embodiment, the first transparent conductive oxide layer comprises indium tin oxide (ITO), and the second transparent conductive oxide layer comprises indium zinc oxide (IZO). In another embodiment, a material for the first transparent conductive oxide layer and the second transparent conductive oxide layer is selected from the group consisting of indium tin oxide (ITO), aluminum zinc oxide (AZO), cadmium tin oxide, antimony tin oxide, zinc oxide (ZnO), zinc tin oxide (ZTO), and indium zinc oxide (IZO). The reflective layer 204 comprises a metal material for reflecting light emitted by the light-emitting stack 202. In the present embodiment, the reflective layer 204 has a reflectivity greater than 80% to light emitted by the light-emitting stack 202. For example, the metal reflective layer 204 comprises gold (Au), silver (Ag), or Al (Aluminum). A barrier layer (not shown) is optionally disposed on the reflective layer 204 for preventing the metal material of the reflective layer 204 from diffusing into the metal connecting structure 205. The metal connecting structure 205 comprises an alloy of indium (In) and gold (Au). The patterned contact layer 206 comprises a material which forms an ohmic contact with the light-emitting stack 202. In the present embodiment, the patterned contact layer 206 comprises a layer of Au-Ge-Ni alloy with a thickness of about from 300 nm to 700 nm on the surface S1. The patterned contact layer 206 comprises a plurality of contact dots separated from each other when viewed from a top of the light-emitting device 20 as shown in FIG. 3.

The smoothing layer 208 comprises a thermosetting material. The smoothing layer 208 comprises an electrically conductive material or an electrically non-conductive material. For example, the electrically conductive material comprises a conducting polymer or a mixture of a non-conductive polymer and a conductive material. The non-conductive polymer comprises epoxy. The electrically non-conductive material comprises a non-conductive polymer or a mixture of a non-conductive polymer and other non-conductive material. The non-conductive polymer comprises epoxy. The conducting polymer comprises poly (3,4-ethylenedioxythiophene) polystyrene sulfonate (i.e., PEDOT: PSS), and has an electrical resistivity smaller than 10⁻¹ Ω-m.

The mixture of a non-conductive polymer and a conductive material comprises epoxy mixed with silver (Ag) nano-particles, carbon nanotubes (CNTs), or graphene flake having a thickness of about 30 nm and a dimension of about from 50 nm to 2 um. When the smoothing layer 208 comprises the mixture of epoxy and silver (Ag) nano-particles, the smoothing layer 208 forms an ohmic contact with the light-emitting stack 202 by the silver (Ag) nano-particles. Accordingly, an electrical path is formed in addition to the patterned contact layer 206. A refractive index of the smoothing layer 208 is smaller than a refractive index of the light-emitting stack 202 and is larger than or equal to a refractive index of a layer over the smoothing layer 208, such as the transparent conductive layer 209. The smoothing layer 208 comprises a transmittance over 70% to light emitted by the active layer 202b. In one embodiment, the smoothing layer 208 formed by poly (3,4-ethylenedioxythiophene) polystyrene sulfonate (i.e., PEDOT: PSS) shows a good transmittance of 86.9% to light having a wavelength of 620 nm while has a sheet resistance of about 200 ohm per square, which is equal or close to a sheet resistance of a ITO film having a thickness of about 800 Å. In other words, the smoothing layer 208 provides a layer with a smaller roughness than the roughness of the surface S1 and also improves current conducting between the contact dots of the patterned contact layer 206. The transparent conductive layer 209 comprises a transparent conductive oxide layer or a thin metal layer having a thickness less than 500 Å. A material for the transparent conductive oxide layer comprises indium tin oxide (ITO), aluminum zinc oxide (AZO), cadmium tin oxide, antimony tin oxide, zinc oxide (ZnO), zinc tin oxide (ZTO), or indium zinc oxide (IZO). A material for the thin metal layer may be aluminum, gold, platinum, zinc, silver, nickel, germanium, indium, or tin, or the metal alloy thereof.

FIG. 3 shows a top view of the light-emitting device 20 in FIG. 2I. The patterned contact layer 206 comprises a plurality of contact dots separated from each other. Each of the contact dots have a diameter of about 3˜15 μm. The light-emitting device 20 is devoid of any extending electrode extending from the first bonding pad 210E1. Less light is shielded by the light-emitting device 20, and the light-emitting efficiency is enhanced accordingly. The ratio of the area of the plurality of contact dots to the area of the top surface of the light-emitting stack 202 is about 0.5˜6%, and is about 1˜3% in another embodiments.

The above-mentioned embodiments are only examples to illustrate the theory of the present invention and its effect, rather than be used to limit the present application. Other alternatives and modifications may be made by a person of ordinary skill in the art of the present application without departing from the spirit and scope of the application, and are within the scope of the present application.

1. A light-emitting device comprising:
a light-emitting stack comprising an active layer and a first surface comprising a roughened area, wherein the first surface is an outermost surface of the light-emitting stack;
a smoothing layer on the first surface, wherein the smoothing layer has a surface smoother than the first surface; and
a transparent conductive layer on the smoothing layer.

2. The light-emitting device as claimed in claim 1, wherein the first surface further comprises an un-rough area, and a patterned contact layer is on the un-rough area.

3. The light-emitting device as claimed in claim 1, further comprising a bonding pad on the transparent conductive layer.

4. The light-emitting device as claimed in claim 1, wherein a surface roughness of the roughened area is greater than 0.5 um by measuring from a cross-sectional length of 50 μm of the first surface.

5. The light-emitting device as claimed in claim 1, wherein a surface roughness of the surface of the smoothing layer is smaller than 100 nm by measuring from a cross-sectional length of 50 μm of the smoothing layer.

6. The light-emitting device as claimed in claim 2, wherein the patterned contact layer comprises a plurality of contact dots separated from each other.

7. The light-emitting device as claimed in claim 2, wherein the patterned contact layer forms an ohmic contact with the light-emitting stack.

8. The light-emitting device as claimed in claim 1, wherein the smoothing layer comprises a thermosetting material.

9. The light-emitting device as claimed in claim 1, wherein the smoothing layer comprises an electrically conductive material.

10. The light-emitting device as claimed in claim 1, wherein the smoothing layer has an electrical resistivity smaller than 10⁻¹ Ω-m.

11. The light-emitting device as claimed in claim 1, wherein the smoothing layer comprises a conducting polymer, a mixture of epoxy and a conductive material, epoxy, or a mixture of epoxy and a non-conductive material.

12. The light-emitting device as claimed in claim 11, wherein the conducting polymer comprising poly (3,4-ethylenedioxythiophene) polystyrene sulfonate (PEDOT: PSS).

13. The light-emitting device as claimed in claim 1, wherein the smoothing layer forms an ohmic contact with the light-emitting stack.

14. The light-emitting device as claimed in claim 1, the smoothing layer comprises a transmittance over 70% to light emitted by the active layer.

15. A method to form a light-emitting device comprising:
forming a light-emitting stack comprising an active layer and a first surface comprising a roughened area, wherein the first surface is an outermost surface of the light-emitting stack;
forming a smoothing layer on the first surface, wherein the smoothing layer has a surface smoother than the first surface; and
forming a transparent conductive layer on the smoothing layer.

16. The method to form a light-emitting device as claimed in claim 15, wherein the first surface comprises an un-rough area, and the method further comprises forming a patterned contact layer on the un-rough area.

17. The method to form a light-emitting device as claimed in claim 15, further comprising forming a bonding pad on the transparent conductive layer.

18. The method to form a light-emitting device as claimed in claim 15, wherein a surface roughness of the roughened area is greater than 0.5 μm by measuring from a cross-sectional length of 50 μm of the first surface.

19. The method to form a light-emitting device as claimed in claim 15, further comprising thermally curing the smoothing layer, wherein the smoothing layer comprises a thermosetting material.

20. The method to form a light-emitting device as claimed in claim 19, further comprising applying an ultrasonic treatment to the smoothing layer prior to the thermally curing step.
